(19) United States
(12) Patent Application Publication
(10) Pub. No.: US 2026/0020391 A1
(43) Pub. Date: Jan. 15, 2026

(54) LUMIPHORIC MATERIAL STRUCTURES WITHIN LIGHT-EMITTING DIODES AND RELATED METHODS

(71) Applicant: CreeLED, Inc., Durham, NC (US)

(72) Inventors: Steven Wuester, Wake Forest, NC (US); Michael Check, Holly Springs, NC (US); Nikolas Hall, Durham, NC (US); Daniel Carleton Driscoll, Cary, NC (US)

(21) Appl. No.: 18/770,162

(22) Filed: Jul. 11, 2024

(51) Int. Cl. H01L 33/50; H01L 33/00; H01L 33/10; H01L 33/24

(52) U.S. Cl. CPC H10H 20/8511; H10H 20/013; H10H 20/814; H10H 20/821; H10H 20/0361

(57) ABSTRACT

Solid-state lighting devices including light-emitting diodes (LEDs) and more particularly arrangements of lumiphoric materials within LEDs and related methods are disclosed. Lumiphoric materials are incorporated or otherwise embedded within LED chips and LED wafers. Embedded lumiphoric materials are provided so that at least some portions of light generated by active LED structures are subject to wavelength conversion before exiting LED chip surfaces. Lumiphoric material layers include arrangements of lumiphoric particles and binder layers positioned between reflective layers and active LED structures. Lumiphoric material layers and/or lumiphoric particles may be patterned within regions of LED chips and/or LED wafers. Related methods include depositing lumiphoric particles and binder layers before reflective layers in LED chips and LED wafers.

### FIELD OF THE DISCLOSURE

The present disclosure relates to solid-state lighting devices including light-emitting diodes (LEDs) and more particularly to arrangements of lumiphoric materials within LEDs and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions. Lumiphoric materials may be arranged such that at least some light generated from the active regions of LED chips is converted to a different wavelength.

LED packages have been developed that provide mechanical support, electrical connections, and encapsulation for LED emitters and lumiphoric materials. As LED technology continues to advance, LED chips and related packages are needed that emit light of high color quality for various applications. Despite recent advances in LED technology, challenges remain for producing high quality light with desired emission characteristics while also providing high light emission efficiency in LED chips and packages.

The art continues to seek improved LEDs and solid-state lighting devices having desirable illumination characteristics capable of overcoming challenges associated with conventional LED devices.

### SUMMARY

The present disclosure relates to solid-state lighting devices including light-emitting diodes (LEDs) and more particularly to arrangements of lumiphoric materials within LEDs and related methods. Lumiphoric materials are incorporated or otherwise embedded within LED chips and LED wafers. Embedded lumiphoric materials are provided so that at least some portions of light generated by active LED structures are subject to wavelength conversion before exiting LED chip surfaces. Lumiphoric material layers include arrangements of lumiphoric particles and binder layers positioned between reflective layers and active LED structures. Lumiphoric material layers and/or lumiphoric particles may be patterned within regions of LED chips and/or LED wafers. Related methods include depositing lumiphoric particles and binder layers before reflective layers in LED chips and LED wafers.

In one aspect, an LED chip comprises: an active LED structure comprising an n-type layer, a p-type layer, and an active layer between the n-type layer and the p-type layer; a dielectric reflective layer on the active LED structure; and a lumiphoric material layer between the dielectric reflective layer and the active LED structure, the lumiphoric material layer configured for wavelength conversion of at least a portion of light generated by the active LED structure. The LED chip may further comprise a metal reflective layer on the dielectric reflective layer such that the dielectric reflective layer is between the metal reflective layer and the lumiphoric material layer. In certain embodiments, a lateral edge of the of the lumiphoric material layer is bound by the dielectric reflective layer. In certain embodiments, the active LED structure forms a mesa sidewall along portions of the p-type layer, the active layer, and the n-type layer, and the lateral edge of the lumiphoric layer is aligned with the mesa sidewall. In certain embodiments, the dielectric reflective layer extends along the mesa sidewall. In certain embodiments, the lumiphoric material layer comprises a plurality of lumiphoric particles and a binder layer. In certain embodiments, the binder layer comprises aluminum oxide. In certain embodiments, the lumiphoric material layer comprises a plurality of lumiphoric particles arranged in a pattern of regions within a binder layer.

In another aspect, a method comprises: providing an active LED structure comprising an n-type layer, a p-type layer, and an active layer between the n-type layer and the p-type layer; depositing a plurality of lumiphoric particles on the active LED structure; deposing a binder layer on the plurality of lumiphoric particles to form a lumiphoric material layer comprising the plurality of lumiphoric particles and the binder layer, the lumiphoric material layer configured for wavelength conversion of at least a portion of light generated by the active LED structure; and forming a dielectric reflective layer on the lumiphoric material layer such that the lumiphoric material layer is between the dielectric reflective layer and the active LED structure. In certain embodiments, depositing the binder layer comprises atomic layer deposition. In certain embodiments, the binder layer comprises aluminum oxide. The method may further comprise selectively removing portions of the plurality of lumiphoric particles over portions of the active LED structure before depositing the binder layer. In certain embodiments, the selectively removing portions of the plurality of lumiphoric particles comprises positioning an imprint stamp on the plurality of lumiphoric particles and lifting the imprint stamp away from the active LED structure to selectively remove the portions of the plurality of lumiphoric particles. In certain embodiments, the imprint stamp comprises a plurality of pedestals that contact the plurality of lumiphoric particles. The method may further comprise forming a surface layer on the plurality of pedestals. The method may further comprise forming a metal reflective layer on the dielectric reflective layer such that the dielectric reflective layer is between the metal reflective layer and the lumiphoric material layer.

In another aspect, an LED wafer comprises: an active LED structure comprising an n-type layer, a p-type layer, and an active layer between the n-type layer and the p-type layer; and a lumiphoric material layer forming a pattern on the active LED structure, the lumiphoric material layer configured for wavelength conversion of at least a portion of light generated by the active LED structure. In certain embodiments, the lumiphoric material layer comprises a plurality of lumiphoric particles and a binder layer. In certain embodiments, the binder layer comprises aluminum oxide. In certain embodiments, the plurality of lumiphoric particles are arranged in a pattern of regions within the binder layer.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of an LED chip according to principles of the present disclosure.

FIG. 2A is a cross-sectional view of the LED chip of FIG. 1 at a wafer level fabrication step after lumiphoric particles are formed according to principles of the present disclosure.

FIG. 2B is a cross-sectional view of the LED chip of FIG. 2A at a subsequent wafer level fabrication step after a binder layer is formed on the lumiphoric particles to form a lumiphoric material layer.

FIG. 2C is a cross-sectional view of the LED chip of FIG. 2B at a subsequent wafer level fabrication step after a photoresist is formed on the lumiphoric material layer.

FIG. 2D is a cross-sectional view of the LED chip of FIG. 2C at a subsequent wafer level fabrication step after the lumiphoric material layer is patterned according to the photoresist.

FIG. 2E is a cross-sectional view of the LED chip of FIG. 2D at a subsequent wafer level fabrication step after removal of the photoresist of FIG. 2D.

FIG. 2F is a cross-sectional view of the LED chip of FIG. 2E at a subsequent wafer level fabrication step after mesa sidewalls of the active LED structure are formed.

FIG. 2G is a cross-sectional view of the LED chip of FIG. 2F at a subsequent wafer level fabrication step after formation of a dielectric reflective layer.

FIG. 2H is a cross-sectional view of the LED chip of FIG. 2G at a subsequent wafer level fabrication step after formation of a reflective layer.

FIG. 2I is a cross-sectional view of the LED chip of FIG. 2H after a subsequent fabrication step where additional portions of the LED chip are formed.

FIG. 3A is a cross-sectional view of a fabrication step for an imprint stamp that may be implemented for imprint lithography to form an LED chip according to principles of the present disclosure.

FIG. 3B is a cross-sectional view of the imprint stamp of FIG. 3A at a subsequent fabrication step after portions of an imprint wafer are subject to a removal process.

FIG. 3C is a cross-sectional view of the imprint stamp of FIG. 3B at a subsequent fabrication step after removal of a photoresist.

FIG. 3D is a cross-sectional view of the imprint stamp of FIG. 3C at a subsequent fabrication step after a surface layer is formed on the imprint wafer.

FIG. 4A is a simplified cross-sectional view of an LED chip at a similar fabrication step as FIG. 2A.

FIG. 4B is a cross-sectional view of the LED chip of FIG. 4A with the imprint stamp of FIG. 3D in place for patterning lumiphoric particles.

FIG. 4C is a cross-sectional view of the LED chip of FIG. 4B after the imprint stamp of FIG. 4B is lifted away from the active LED structure.

FIG. 4D is a cross-sectional view of the LED chip of FIG. 4C after a binder layer is provided to form a lumiphoric material layer with the lumiphoric particles.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to arrangements of lumiphoric materials within LEDs and related methods. Lumiphoric materials are incorporated or otherwise embedded within LED chips and LED wafers. Embedded lumiphoric materials are provided so that at least some portions of light generated by active LED structures are subject to wavelength conversion before exiting LED chip surfaces. Lumiphoric material layers include arrangements of lumiphoric particles and binder layers positioned between reflective layers and active LED structures. Lumiphoric material layers and/or lumiphoric particles may be patterned within regions of LED chips and/or LED wafers. Related methods include depositing lumiphoric particles and binder layers before reflective layers are deposited in LED chips and LED wafers.

Before delving into specific details of various aspects of the present disclosure, an overview of various elements that may be included in exemplary LED devices of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, current-spreading layers, and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include silicon carbide (SiC), organic semiconductor materials, and other Group III-V systems such as gallium phosphide (GaP), gallium arsenide (GaAs), and related compounds. The active LED structure may be grown on a growth substrate that can include many materials, such as sapphire, SiC, aluminum nitride (AlN), and GaN.

Different embodiments of the active LED structure can emit different wavelengths of light depending on the composition of the active layer and n-type and p-type layers. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm. Other wavelength ranges include a range from 400 nm to about 430 nm and/or a range from 480 nm to 500 nm, among others, or any wavelength in a range from 400 nm to 750 nm. In certain embodiments, the active LED structure may be configured to emit light that is outside the visible spectrum, including infrared (IR) or one or more portions of the ultraviolet (UV) spectrum. The IR spectrum may encompass wavelengths from 700 nm to 1000 nm. The UV spectrum is typically divided into three wavelength range categories denotated with letters A, B, and C. UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

As used herein, a layer or region of a light-emitting device may be considered to be "transparent" when at least 80% of emitted radiation that impinges on the layer or region emerges through the layer or region. Moreover, as used herein, a layer or region of an LED is considered to be "reflective" or embody a “mirror” or a "reflector" when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure may be useful for LED chips having a variety of geometries, including flip-chip geometries. Flip-chip structures for LED chips typically include anode and cathode connections that are provided from a same side or face of the LED chip. The anode and cathode side is typically structured as a mounting face of the LED chip for flip-chip mounting to another surface, such as a printed circuit board. In this regard, the anode and cathode connections on the mounting face serve to mechanically bond and electrically couple the LED chip to the other surface. When flip-chip mounted, the opposing side or face of the LED chip corresponds with a light-emitting face that is oriented toward an intended emission direction. In certain embodiments, a growth substrate for the LED chip may form and/or be adjacent to the light-emitting face when flip-chip mounted. During chip fabrication, the active LED structure may be epitaxially grown on the growth substrate. Other applicable LED chip geometries include vertical with anode and cathodes on opposing sides, and/or structures where growth substrates are removed and active LED structures are supported by carrier substrates.

LED chips as described herein may be well suited for placement in LED packages that may include one or more elements, such as cover structures with additional lumiphoric materials or phosphors for wavelength conversion, encapsulants, light-altering materials, lenses, and electrical contacts, among others, that are provided with one or more LED chips. Such LED packages may include a support structure or member, such as a submount or a lead frame. A support structure may refer to a structure of an LED package that supports one or more other elements of the LED package, including but not limited to LED chips and cover structures. In certain embodiments, a support structure may include a submount on which an LED chip is mounted. Suitable materials for a submount include, but are not limited to, ceramic materials such as aluminum oxide or alumina, AlN, or organic insulators like polyimide (PI) and polyphthalamide (PPA). In other embodiments a submount may comprise a printed circuit board (PCB), sapphire, Si, or any other suitable material. For PCB embodiments, different PCB types can be used such as standard FR-4 PCB, metal core PCB, or any other type of PCB. In still further embodiments, the support structure may embody a lead frame structure.

Lumiphoric materials (also referred to herein as luminophores) are positioned to receive and absorb at least some of the light from an LED chip and convert such light to one or more different wavelength spectra according to the characteristic emission from the lumiphoric materials. In this regard, at least one luminophore receiving at least a portion of the light generated by the LED chip may re-emit light having a different peak wavelength than the LED source. An LED chip and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of from 2500 Kelvin (K) to 10,000 K. In certain embodiments, lumiphoric materials having cyan, green, amber, yellow, orange, and/or red peak wavelengths may be used. In some embodiments, the combination of the LED chip and the one or more luminophores (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. In still further embodiments, an LED chip may be configured to emit light outside the visible spectrum, such as UV light, and the lumiphoric materials may convert at least a portion of the UV light to visible light. In other embodiments, the LED chip may be configured to emit visible light and lumiphoric materials may be provided that convert at least a portion of the visible light to IR or UV wavelengths.

Lumiphoric materials as described herein may be or include one or more of a phosphor, a scintillator, a lumiphoric ink, a quantum dot material, a day glow tape, and the like. Lumiphoric materials may be provided by any suitable means, for example, dispersal of particles in a host material or an encapsulant material. In certain embodiments, lumiphoric materials may be downconverting or upconverting, and combinations of both downconverting and upconverting materials may be provided. In certain embodiments, multiple different (e.g., compositionally different) lumiphoric materials that are arranged to produce different peak wavelengths may be arranged to receive emissions from one or more LED chips. In certain embodiments, one or more lumiphoric materials may be arranged in a substantially uniform manner. In other embodiments, one or more lumiphoric materials may be arranged in a manner that is non-uniform with respect to one or more of material composition, concentration, and thickness. In certain embodiments, the loading percentage of one or more lumiphoric materials may be varied relative to one or more positions of an LED chip. In certain embodiments, one or more lumiphoric materials may be patterned to include one or more stripes, dots, curves, or polygonal shapes. In certain embodiments, multiple lumiphoric materials may be arranged in different discrete regions or discrete layers for an LED chip.

Typical LED chips exhibit narrowband emissions according to bandgaps and/or other arrangements provided by their active LED structures. Lumiphoric materials, which convert portions of these narrowband emissions to other wavelengths, serve to broaden the aggregate emissions of the overall devices. Lumiphoric materials are typically formed on or over LED chips after such LED chips are substantially fabricated. For example, an LED chip may be mounted within a package and lumiphoric materials may be formed thereon, such as by dispensing or spray-coating. In another example, lumiphoric materials may be added to a top surface of a fully fabricated LED chip before mounting within a package.

According to aspects of the present disclosure, lumiphoric materials may be incorporated or otherwise embedded within LED chips during fabrication thereof. In this regard, such LED chips may emit broader emissions and may be used alone or in combination with additional lumiphoric materials provided over top surfaces of the LED chips. In certain embodiments, the embedded lumiphoric materials may provide light with a peak wavelength that is different than both the active LED structure of the LED chip and the additional lumiphoric materials in order to provide further broadened emissions. For example, the emissions of the embedded lumiphoric materials may be configured to fill a portion of an emission spectrum that is between the active LED structure and the additional lumiphoric materials. In other embodiments, embedded lumiphoric materials may be configured to convert portions of visible light from the active LED structure to nonvisible wavelengths, such as IR or UV.

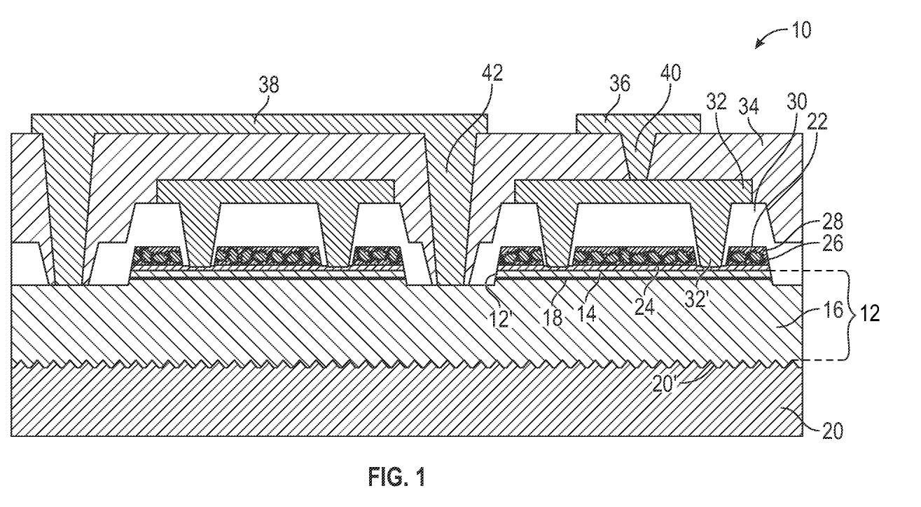

FIG. 1 is a cross-sectional view of an LED chip 10 according to principles of the present disclosure. The LED chip 10 includes an active LED structure 12 comprising a p-type layer 14, an n-type layer 16, and an active layer 18 formed on a substrate 20. In FIG. 1, the LED chip 10 is illustrated with an orientation for flip-chip mounting. In certain embodiments, one or more buffer layers and/or undoped layers may be provided between the substrate 20 and the active LED structure 12. The substrate 20 may embody a patterned substrate such that a surface 20’ of the substrate 20 closest to the active LED structure 12 is patterned. In certain embodiments, the n-type layer 16 is between the active layer 18 and the substrate 20. In other embodiments, the doping order may be reversed. The substrate 20 may comprise many different materials such as SiC or sapphire and can have one or more surfaces that are shaped, textured, or patterned to enhance light extraction. In certain embodiments, the substrate 20 is light transmissive (preferably transparent) and may include a patterned surface 20’ that is proximate the active LED structure 12 and includes multiple recessed and/or raised features. The LED chip 10 may embody a flip-chip structure that may be inverted from the perspective of FIG. 1 such that the substrate 20 forms a top light emitting surface.

In FIG. 1, a lumiphoric material layer 22 is provided on portions of the p-type layer 14 with a current spreading layer 24 therebetween. The lumiphoric material layer 22 may comprise many different materials and in some examples may be a multiple layer structure. In certain embodiments, the lumiphoric material layer 22 includes lumiphoric particles 26 with a binder layer 28 formed to hold the lumiphoric particles 26 in place. The lumiphoric particles 28 may comprise phosphor particles or even plasmonic material or particles in proximity with the phosphor particles. When present, plasmonic materials may be configured to induce localized surface plasmon resonance and excite a corresponding localized surface plasmon enhanced electric field in response to incident light, thereby providing increased photoluminescence of lumiphoric materials. In certain embodiments, plasmonic materials may include metal and/or metal nitride particles with a dielectric coating. As will be later described in greater detail, the lumiphoric particles 26 may first be applied on the active LED structure 12 and/or current spreading layer 24 followed by deposition of the binder layer 28. In certain aspects, the binder layer 28 may conformally cover the lumiphoric particles 26. The binder layer 28 may comprise various materials, including silicon dioxide (SiO₂) and/or aluminum oxide (AlO, AlₓO_{y}, Al₂O₃), among others. The current spreading layer 24 may embody a layer of conductive material, for example a transparent conductive oxide such as indium tin oxide (ITO) or a metal such as platinum (Pt), although other materials may be used. In still further embodiments, the current spreading layer 24 may be omitted.

In FIG. 1, a dielectric reflective layer 30 is provided on portions of the lumiphoric material layer 22. The dielectric reflective layer 30 may comprise many different materials and preferably comprises a material that presents an index of refraction step with the material of the active LED structure 12 to promote total internal reflection (TIR) of light generated from the active LED structure 12. Light that experiences TIR is redirected without experiencing absorption or loss and can thereby contribute to useful or desired LED chip emission. In certain embodiments, the dielectric reflective layer 30 comprises a material with an index of refraction lower than the index of refraction of the active LED structure material. The dielectric reflective layer 30 may comprise many different materials, with some having an index of refraction less than 2.3, while others can have an index of refraction less than 2.15, less than 2.0, and less than 1.5. In certain embodiments, the dielectric reflective layer 30 comprises SiO₂ and/or silicon nitride (SiN). It is understood that many dielectric materials can be used such as SiN, SiNx, Si₃N₄, Si, germanium (Ge), SiO₂, SiOx, titanium dioxide (TiO₂), tantalum pentoxide (Ta₂O₅), ITO, magnesium oxide (MgOx), zinc oxide (ZnO), and combinations thereof.

In certain embodiments, the dielectric reflective layer 30 may include multiple alternating layers of different dielectric materials, e.g., alternating layers of SiO₂ and SiN that symmetrically repeat or are asymmetrically arranged. The dielectric reflective layer 30 may have different thicknesses depending on the type of materials used, with some embodiments having a thickness of at least 0.2 microns (μm). In some of these embodiments, the dielectric reflective layer 30 can have a thickness in the range of 0.2 μm to 0.7 μm, while in some of these embodiments the thickness can be approximately 0.5 μm. Portions of the dielectric reflective layer 30 may extend along mesa sidewalls 12’ of the active LED structure 12 (e.g., along sidewall portions of the p-type layer 14, the active layer 18, and the n-type layer 16). As illustrated, the lumiphoric material layer 22 may be confined along a top of the active LED structure 12 and/or current spreading layer 24, thereby not extending along the mesa sidewalls 12’. In this manner, lateral edges and/or sidewalls of the lumiphoric material layer 22 may be bounded by the dielectric reflective layer 30 such that the lumiphoric material layer 22 is essentially embedded in the dielectric reflective layer 30. Furthermore, the mesa sidewalls 12’ may define locations where the lateral edges and/or sidewalls of the lumiphoric material layer 22 are aligned with the mesa sidewalls 12’. With such an arrangement, the dielectric reflective layer 30 may directly contact the mesa sidewalls 12’ of the active LED structure 12 for increased reflectivity at the sidewalls 12’ while redirecting light toward the lumiphoric material layer 22 for wavelength conversion.

The LED chip 10 may further include a reflective layer 32 that is on the dielectric reflective layer 30 such that the dielectric reflective layer 30 and lumiphoric material layer 22 are arranged between the active LED structure 12 and the reflective layer 32. The reflective layer 32 may include a metal layer that is configured to reflect any light from the active LED structure 12 that may pass through the dielectric reflective layer 30. The reflective layer 32 may comprise many different materials such as Ag, gold (Au), or combinations thereof. Accordingly, the reflective layer 32 may be referred to as a metal reflector layer and/or a metal reflective layer. As illustrated, the reflective layer 32 may include one or more reflective layer interconnects 32’ that provide electrically conductive paths through the dielectric reflective layer 30 and the lumiphoric material layer 22 to electrically connect with the current spreading layer 24 and/or p-type layer 14. In certain embodiments, the reflective layer interconnects 32’ comprise reflective layer vias. In some embodiments, the reflective layer interconnects 32’ comprise the same material as the reflective layer 32 and are formed at the same time as the reflective layer 32. In other embodiments, the reflective layer interconnects 32’ may comprise a different material than the reflective layer 32.

In certain embodiments, a barrier layer (not illustrated) may be present on a side of the reflective layer 32 opposite the dielectric reflective layer 30 to prevent migration of the reflective layer 32 material, such as Ag, to other layers. Preventing this migration helps the LED chip 10 maintain efficient operation through its lifetime. The barrier layer may comprise an electrically conductive material, with suitable materials including but not limited to sputtered Ti/Pt followed by evaporated Au bulk material or sputtered Ti/Ni followed by an evaporated Ti/Au bulk material.

A passivation layer 34 may be included on the reflective layer 32 and other portions of the LED chip 10. The passivation layer 34 may further be arranged on portions of the dielectric reflective layer 30 that are uncovered by the reflective layer 32. The passivation layer 34 protects and provides electrical insulation for the LED chip 10 and can comprise many different materials, such as a dielectric material. In certain embodiments, the passivation layer 34 is a single layer, and in other embodiments, the passivation layer 34 comprises a plurality of layers. A suitable material for the passivation layer 34 includes but is not limited to SiN, SiNx, and/or Si₃N₄. As illustrated, the dielectric reflective layer 30 may bound perimeter and/or mesa sidewalls 12’ portions of the active LED structure 12, including mesa sidewalls of the p-type layer 14, the active layer 18, and the n-type layer 16 along a perimeter of the LED chip 10. Furthermore, the passivation layer 34 may be arranged to also bound perimeter portions of the active LED structure 12 where the passivation layer 34 extends to the substrate 20. In this manner, portions of the dielectric reflective layer 30 may be arranged between portions of the passivation layer 34 and mesa sidewalls 12’ of the active LED structure 12 for enhanced reflectivity along perimeter edges of active LED structure 12.

In FIG. 1, the LED chip 10 comprises a p-contact 36 and an n-contact 38 that are arranged on the passivation layer 34 and are configured to provide electrical connections with the active LED structure 12. The p-contact 36, which may also be referred to as an anode contact, may comprise one or more p-contact interconnects 40 that extend through the passivation layer 34 to electrically connect with the reflective layer 32 and provide an electrical path to the p-type layer 14. In certain embodiments, the one or more p-contact interconnects 40 comprise one or more p-contact vias. The n-contact 38, which may also be referred to as a cathode contact, is electrically coupled to the n-type layer 16 by way of one or more n-contact interconnects 42 that extend through the passivation layer 34, the reflective layer 32, the dielectric reflective layer 30, the lumiphoric material layer 22, the p-type layer 14, and the active layer 18. In certain embodiments, the one or more n-contact interconnects 42 may be referred to as one or more n-contact vias.

In operation, a signal applied across the p-contact 36 and the n-contact 38 is conducted to the p-type layer 14 and the n-type layer 16, causing the LED chip 10 to emit light from the active layer 18. The p-contact 36 and the n-contact 38 can comprise many different materials such as Au, copper (Cu), nickel (Ni), In, Al, Ag, tin (Sn), Pt, or combinations thereof. In still other embodiments, the p-contact 36 and the n-contact 38 can comprise conducting oxides and transparent conducting oxides such as ITO, nickel oxide (NiO), ZnO, cadmium tin oxide, indium oxide, tin oxide, magnesium oxide, ZnGa₂O₄, ZnO₂/Sb, Ga₂O₃/Sn, AgInO₂/Sn, In₂O₃/Zn, CuAlO₂, LaCuOS, CuGaO₂, and SrCu₂O₂. The choice of material used can depend on the location of the contacts and on the desired electrical characteristics, such as transparency, junction resistivity, and sheet resistance. As described above, the LED chip 10 is arranged for flip-chip mounting and the p-contact 36 and n-contact 38 are configured to be mounted or bonded to a surface, such as a printed circuit board. While FIG. 1 is described in the context of a flip-chip structure, the principles disclosed for one or more of the current spreading layer 24, the lumiphoric material layer 22, the dielectric reflective layer 30, and the reflective layer 32 are readily applicable to other chip structures. For illustrative purposes, FIG. 1 is shown with two n-contact interconnects 42. In practice, the LED chip 10 may include multiple n-contact interconnects 42 spaced apart in an array pattern across the active LED structure 12.

As illustrated in FIG. 1, the lumiphoric material layer 22 is essentially embedded within the LED chip 10. In this manner, the LED chip 10 may be pre-configured to provide additional emission spectrum beyond just the narrow band emissions of the active LED structure 12. As illustrated, the lumiphoric material layer 22 may be arranged between the dielectric reflective layer 30 and the active LED structure 12. Accordingly, at least a portion of downward propagating light from the active layer 18 and toward the dielectric reflective layer 30 may be subject to wavelength conversion before such light is reflected back and ultimately escapes the LED chip 10 through the substrate 20. In this regard, a combination of light having a first peak wavelength generated by the active LED structure 12 and light having a second peak wavelength that is generated by wavelength conversion may concurrently exit the substrate 20. As described above, the lumiphoric material layer 22 may not extend on the mesa sidewalls 12’ of the active LED structure 12. In this regard, at least a portion of laterally propagating light from the active LED structure 12 may also be redirected at the mesa sidewalls 12’ by the dielectric reflective layer 30 toward the lumiphoric material layer 22 for wavelength conversion.

In the flip-chip orientation of FIG. 1, the lumiphoric material layer 22 may also be arranged between the active LED structure 12 and both the p-contact 36 and the n-contact 38. Light scattering may occur within the lumiphoric material layer 22 such that at least a portion of light, converted and/or unconverted, may be scattered and redirected in a desired emission direction. Light scattering effectively increases the likelihood of light propagating along escape cones in order to exit the LED chip 10 in the desired emission direction, such as through the substrate 20. In this regard, light scattering may increase brightness and/or efficiency of the LED chip 10 by reducing light loss due to internal absorption.

The lumiphoric material layer 22 may be formed by various techniques during the fabrication sequence for the LED chip 10. By incorporating the lumiphoric material layer 22 before the final structure of the LED chip 10 is complete, the lumiphoric material layer 22 is effectively embedded within the LED chip 10 to provide the various advantages described above. Exemplary techniques for forming the lumiphoric material layer 22 include sputter deposition with laser annealing, electrospray, electromagnetic brush coating, powder coating, atomic layer deposition, spin coating, electrophoretic deposition, imprint lithography, and/or combinations thereof. The lumiphoric material layer 22 may be formed of a single layer or a multiple layer structure. As will be described in the following fabrication sequences, principles of the present disclosure provide the ability to precisely position the lumiphoric particles 26 and the lumiphoric material layer 22 within certain portions of the LED chip 10 for enhanced wavelength conversion. While the principles described herein are applicable for lumiphoric particles 26 having a variety of particle sizes, various aspects may have benefits for precise positioning of generally small particle sizes such as less than or equal to 2 µm.

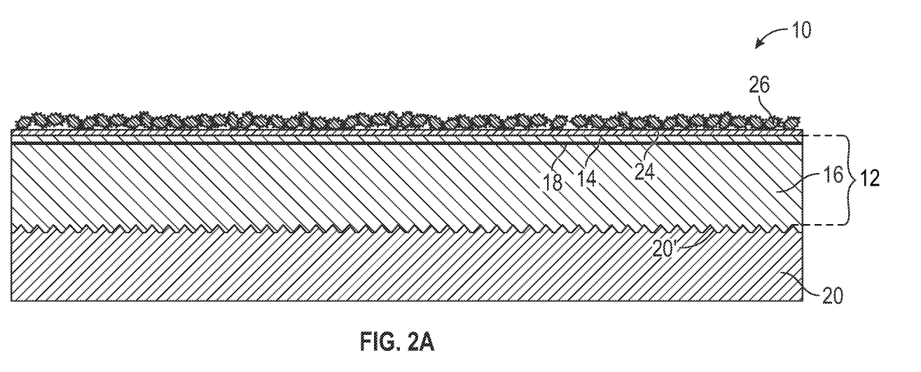

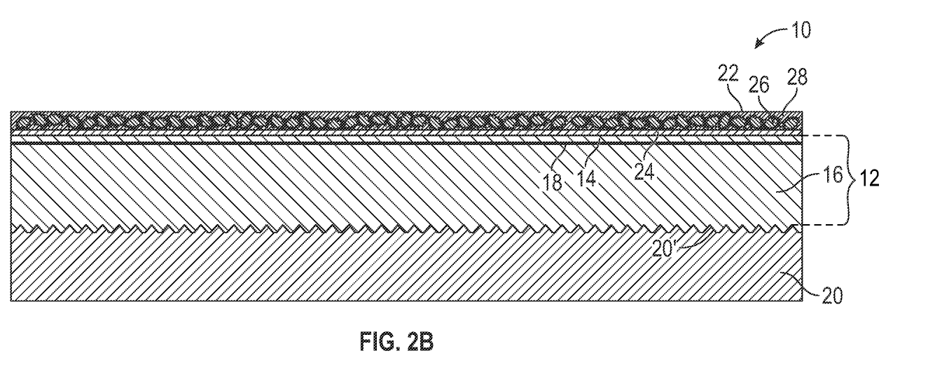

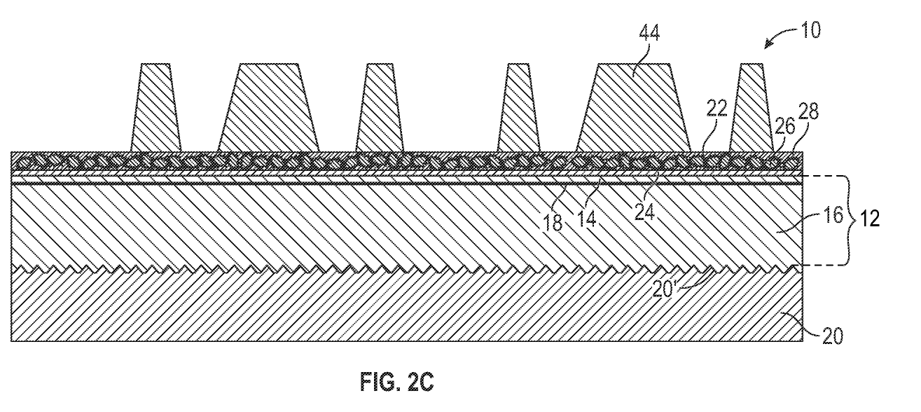

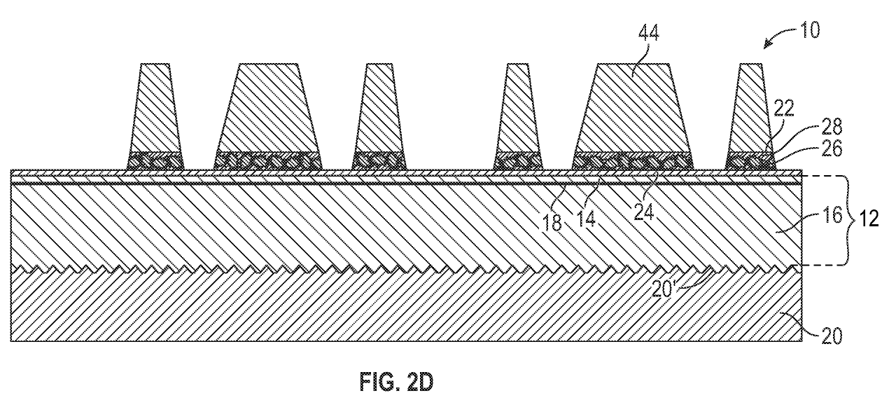

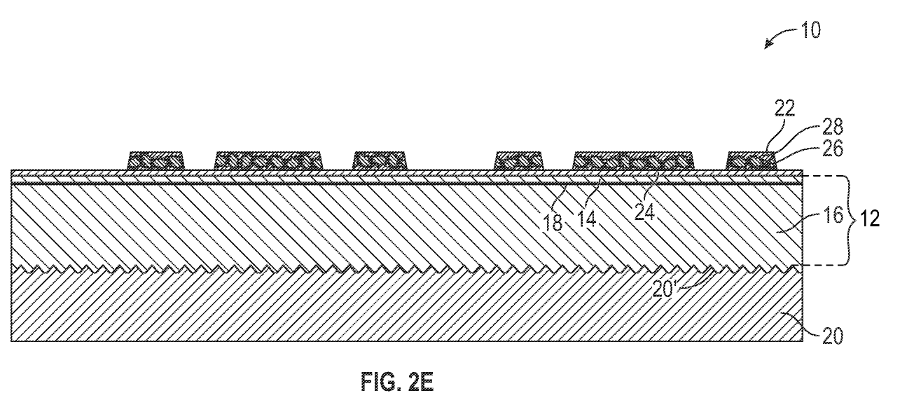

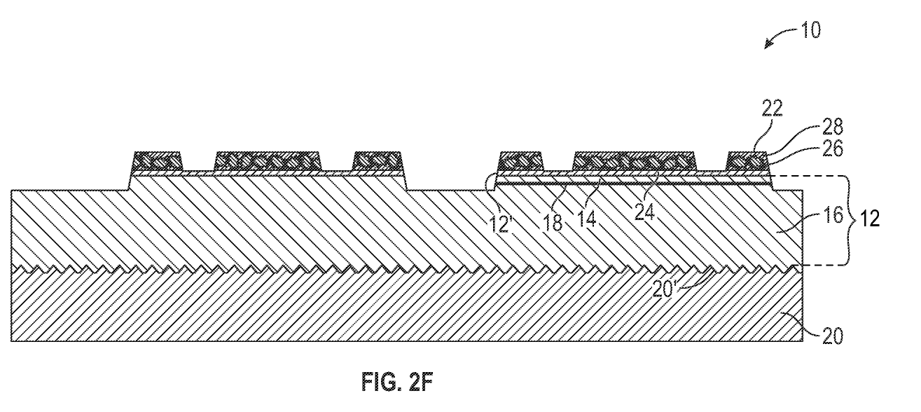

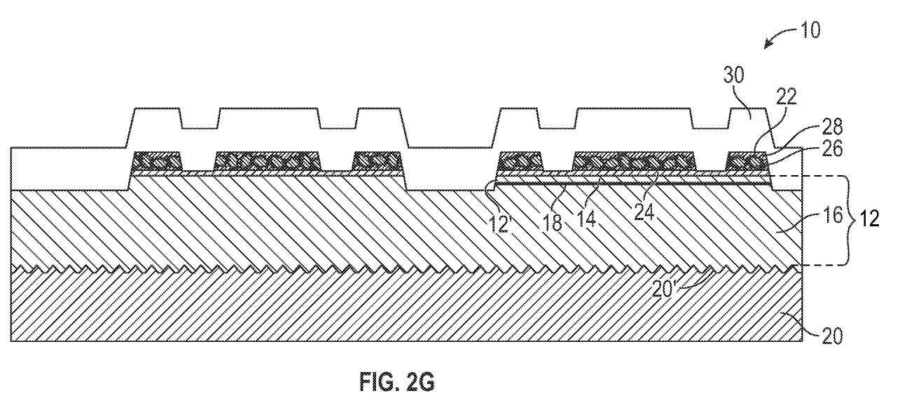

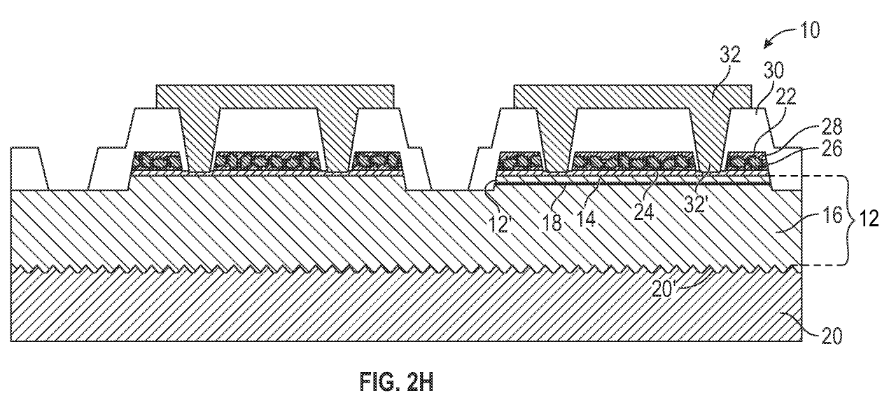

FIGS. 2A to 2I represent cross-sectional views at various steps of an exemplary fabrication sequence for the LED chip 10 of FIG. 1. While FIGS. 2A to 2I are described from the perspective of the individual LED chip 10 of FIG. 1, it is understood each of FIGS. 2A to 2I are typically formed at a wafer level before individual ones of the LED chip 10 are later singulated. In this manner, each of FIGS. 2A to 2I may also represent a portion of an LED wafer where the LED chip 10 is later singulated. In certain embodiments, the fabrication sequence may be stopped at any of FIGS. 2A to 2I for certain manufacturers, and the corresponding LED wafer may then be provided to other manufacturers that complete formation of the LED chip 10 or form alternative LED chip structures. In certain embodiments, the same manufacturer may perform all of FIGS. 2A to 2I to complete formation of the LED chip 10.

FIG. 2A is a cross-sectional view of the LED chip 10 of FIG. 1 at a wafer level fabrication step after the lumiphoric particles 26 are formed on the active LED structure 12 and/or the current spreading layer 24. As illustrated, the lumiphoric particles 26 may be deposited in particle form without having to be premixed within a binder material. In this manner, the lumiphoric particles 26 may be directly formed on the active LED structure 12 and/or the current spreading layer 24 when present. In one example, the lumiphoric particles 26 are deposited by way of spin coating, where the lumiphoric particles 26 are blanket deposited followed by a heating step to bake out residual solvents associated with spin coating.

FIG. 2B is a cross-sectional view of the LED chip 10 of FIG. 2A at a subsequent wafer level fabrication step after the binder layer 28 is formed. The binder layer 28 may be deposited on the lumiphoric particles 26 by way of chemical vapor deposition (CVD), physical vapor deposition (PVD), or atomic layer deposition (ALD), among others. In certain embodiments, the binder layer 28 may conformally cover the lumiphoric particles 26 by conforming to upper surfaces of individual ones of the lumiphoric particles 26.

FIG. 2C is a cross-sectional view of the LED chip 10 of FIG. 2B at a subsequent wafer level fabrication step after a photoresist 44 is formed on the lumiphoric material layer 22. The photoresist 44 may embody a positive resist that is patterned on certain portions of the lumiphoric material layer 22. The photoresist 44 is positioned to protect and/or define regions of the lumiphoric material layer 22 that will remain in the LED chip 10.

FIG. 2D is a cross-sectional view of the LED chip 10 of FIG. 2C at a subsequent wafer level fabrication step after the lumiphoric material layer 22 is patterned according to the photoresist 44. In certain embodiments, a removal process such as etching is performed that effectively removes portions of the lumiphoric material layer 22 in positions uncovered by the photoresist 44.

FIG. 2E is a cross-sectional view of the LED chip 10 of FIG. 2D at a subsequent wafer level fabrication step after removal of the photoresist 44 of FIG. 2D. As illustrated, the lumiphoric material layer 22 is formed in a pattern of regions across the active LED structure 12. Portions of the LED chip 10 that are between adjacent regions of the lumiphoric material layer 22 may define regions for the reflective layer interconnects 32’ and/or the n-contact interconnects 42 of FIG. 1. As described above, the view of FIG. 2E may represent an LED wafer or a portion thereof where the LED chip 10 is later singulated. Accordingly, the LED wafer may include the active LED structure 12, current spreading layer 24, and a lumiphoric material layer 22 formed in a pattern on the active LED structure 12.

FIG. 2F is a cross-sectional view of the LED chip 10 of FIG. 2E at a subsequent wafer level fabrication step after mesa sidewalls 12’ of the active LED structure 12 are formed. The mesa sidewalls 12’ may be formed by a lithography process with another photoresist covering the lumiphoric material layer 22 and underlying portions of the active LED structure 12. After etching and subsequent removal of the photoresist, the mesa sidewalls 12’ are formed, and the etched portions of the active LED structure 12 define areas for the n-contact interconnects 42 of FIG. 1.

FIG. 2G is a cross-sectional view of the LED chip 10 of FIG. 2F at a subsequent wafer level fabrication step after formation of the dielectric reflective layer 30. As illustrated, the dielectric reflective layer 30 may be blanket deposited to cover the pattern of the lumiphoric material layer 22, exposed portions of the current spreading layer 24 and/or p-type layer 14, and portions of the n-type layer 16 that are exposed by the etching process of FIG. 2F. In this regard, the dielectric reflective layer 30 may also be formed on or directly on the mesa sidewalls 12’. By depositing the dielectric reflective layer 30 in this manner, the lumiphoric material layer 22 may be effectively embedded within the dielectric reflective layer 30.

FIG. 2H is a cross-sectional view of the LED chip 10 of FIG. 2G at a subsequent wafer level fabrication step after formation of the reflective layer 32. As illustrated, the reflective layer 32 may be selectively formed on portions of the dielectric reflective layer 30. Before the reflective layer 32 is formed, portions of the dielectric reflective layer 30 that are between regions of the lumiphoric material layer 22 may be removed to provide access to the current spreading layer 24 and/or p-type layer 14. When the reflective layer 32 is deposited, these regions may form the reflective layer interconnects 32’, thereby providing electrically conductive paths through the lumiphoric material layer 22 and the dielectric reflective layer 30 to the active LED structure 12.

FIG. 2I is a cross-sectional view of the LED chip 10 of FIG. 2H after a subsequent fabrication step where the passivation layer 34, the p-contact interconnects 40, the n-contact interconnects 42, the p-contact 36, and the n-contact 38 are formed. If the LED chip 10 is not singulated, then FIG. 2I may represent a portion of an LED wafer that is ready for singulation.

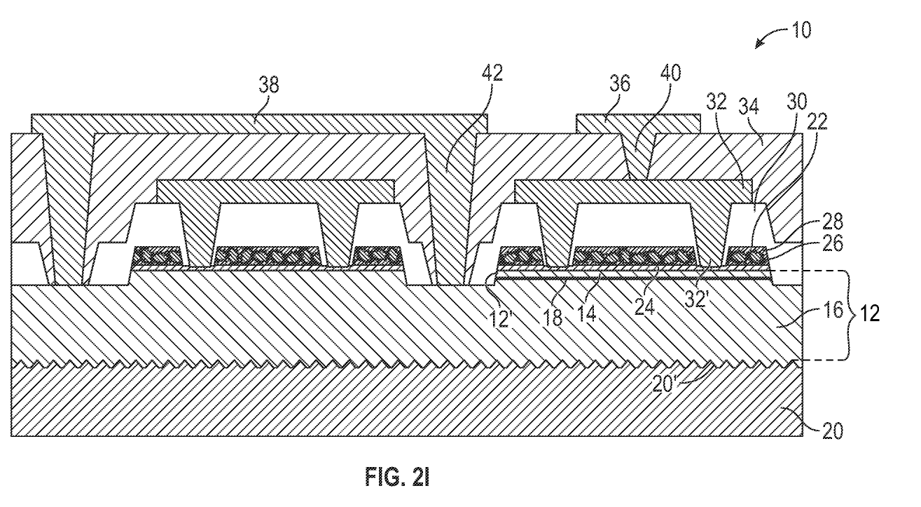

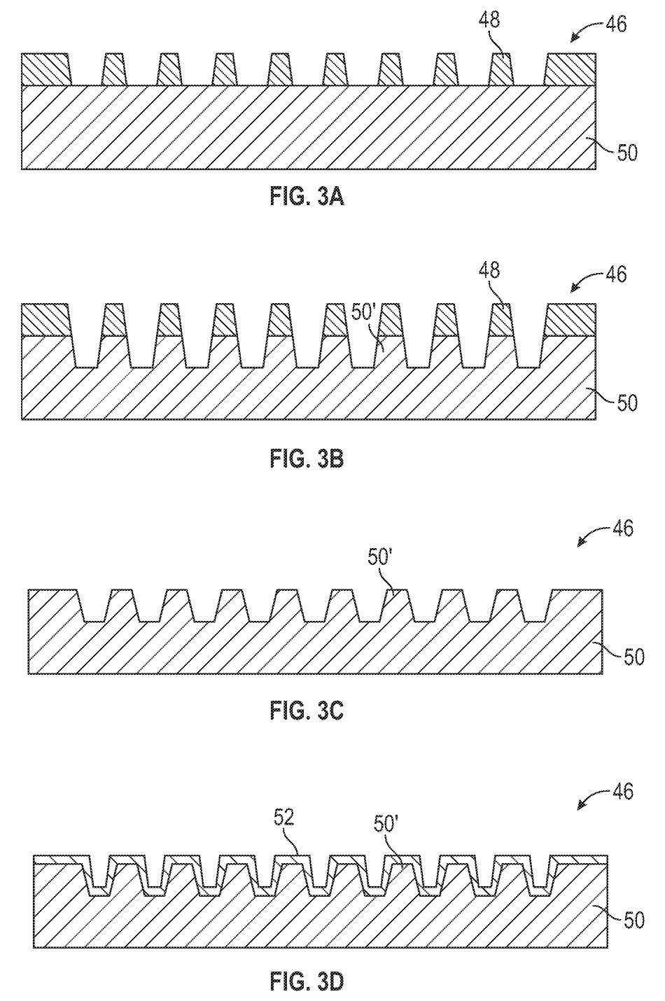

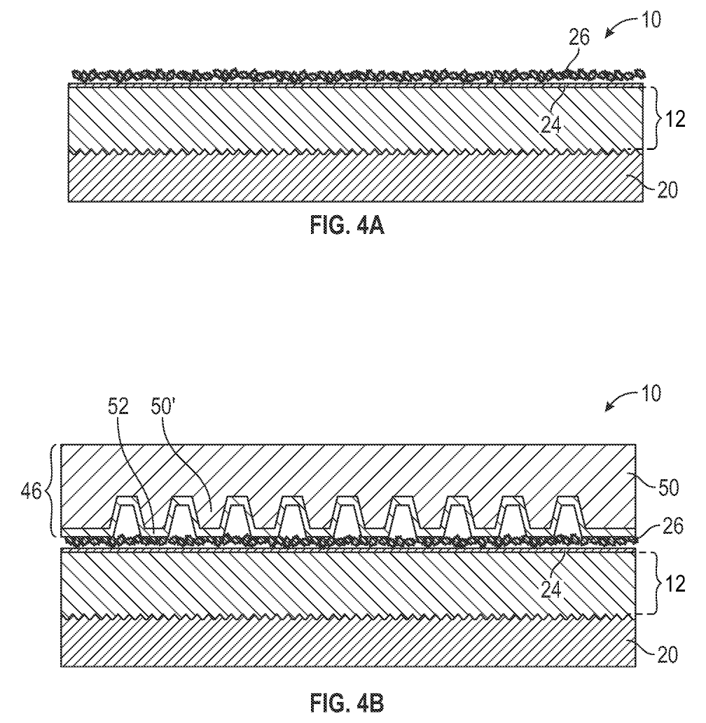

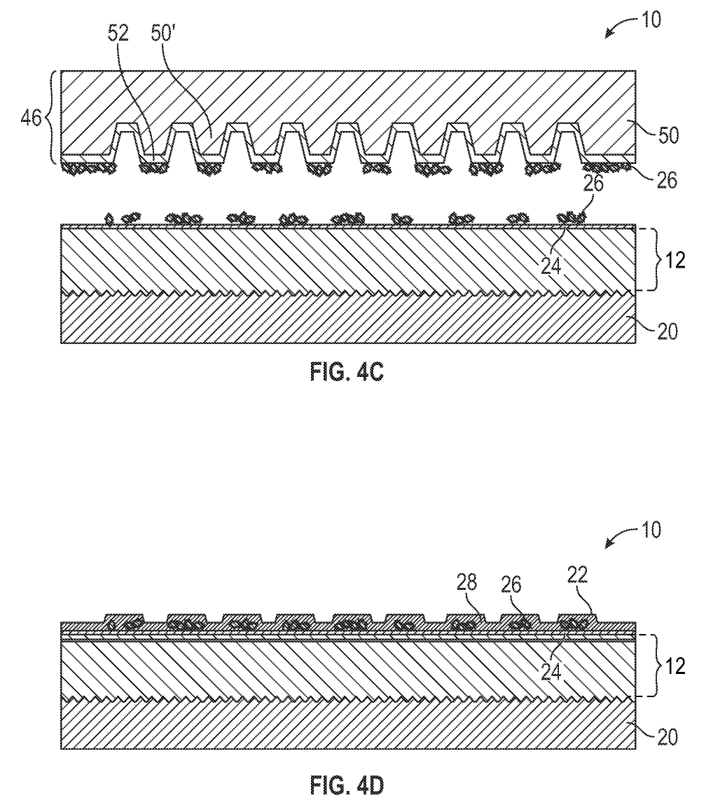

FIGS. 3A to 3D and 4A to 4D represent cross-sectional views at various steps of another exemplary fabrication process involving imprint lithography that may be implemented for the LED chip 10 of FIG. 1. While FIGS. 3A to 3D and 4A to 4D are described from the perspective of the individual LED chip 10 of FIG. 1, it is understood that each of FIGS. 3A to 3D and 4A to 4D may embody wafer level techniques.

FIG. 3A is a cross-sectional view of an imprint stamp 46 for imprint lithography at an initial fabrication step. In FIG. 3A, a photoresist 48 is patterned on an imprint wafer 50. The imprint wafer 50 may comprise many different materials with suitable mechanical stability for imprint lithography, an example of which is a silicon wafer.

FIG. 3B is a cross-sectional view of the imprint stamp 46 of FIG. 3A at a subsequent fabrication step after portions of the imprint wafer 50 are subject to a removal process. For example, an etching step may be performed to remove portions of the imprint wafer 50 that are uncovered by the photoresist 48, thereby forming a plurality of pedestals 50’ of the imprint wafer 50.

FIG. 3C is a cross-sectional view of the imprint stamp 46 of FIG. 3B at a subsequent fabrication step after removal of the photoresist 48 of FIG. 3B. In this manner, the pedestals 50’ of the imprint wafer 50 are exposed. As will be later described with reference to FIGS. 4A to 4D, the pattern of the pedestals 50’ may correspond with areas where the lumiphoric material layer 22 may be removed from the LED chip 10 to arrive at a structure similar to FIG. 2E.

FIG. 3D is a cross-sectional view of the imprint stamp 46 of FIG. 3C at a subsequent fabrication step after a surface layer 52 is formed on the imprint wafer 50. The surface layer 52 may embody a layer of material that is provided on the pedestals 50’ that may assist with removal of lumiphoric material as later described with reference to FIGS. 4A to 4D. In certain embodiments, the surface layer 52 is relatively thin to provide a conformal layer on the imprint wafer 50, thereby conforming to shapes of the pedestals 50’. By way of example, the surface layer 52 may comprise a polymer material, such as polydimethylsiloxane (PDMS).

FIG. 4A is a simplified cross-sectional view of the LED chip 10 at a similar fabrication step described above with reference to FIG. 2A. The lumiphoric particles 26 are formed on the active LED structure 12. As will be described below with reference to FIGS. 4B to 4D, the imprint stamp 46 of FIG. 3D may be utilized to pattern the lumiphoric particles 26 of the LED chip 10 of FIG. 4A.

FIG. 4B is a cross-sectional view of the LED chip 10 of FIG. 4A with the imprint stamp 46 of FIG. 3D in place for patterning the lumiphoric particles 26. As illustrated, the imprint stamp 46 may be applied to the LED chip 10 such that the pedestals 50’ and/or portions of the surface layer 52 on the pedestals 50’ contacts the lumiphoric particles 26. In certain embodiments, the material of the surface layer 52 promotes suitable adhesion with contacted portions of the lumiphoric particles 26.

FIG. 4C is a cross-sectional view of the LED chip 10 of FIG. 4B after the imprint stamp 46 of FIG. 4B is lifted away from the active LED structure 12. As illustrated, portions of the lumiphoric particles 26 that contacted the imprint stamp 46 are also lifted away from the active LED structure 12. In this regard, the remaining lumiphoric particles 26 are formed in a pattern across the active LED structure 12. Portions of the active LED structure 12 where lumiphoric particles 26 are removed may define etch locations for the reflective layer interconnects 32’ and/or the n-contact interconnects 42 as illustrated in FIG. 1.

FIG. 4D is a cross-sectional view of the LED chip 10 of FIG. 4C after the binder layer 28 is provided. The binder layer 28 may be formed by way of CVD, PVD, or ALD, among others. Notably, the resulting lumiphoric material layer 22 includes lumiphoric particles 26 that are effectively patterned as regions within the binder layer 28 that are separated by other areas of the binder layer 28 that are devoid of the lumiphoric particles 26. In certain embodiments, when the dielectric reflective layer 30 is etched with reference to FIGS. 2G and 2H, portions of the binder layer 28 that are devoid of the lumiphoric particles 26 may be concurrently etched to provide access for the reflective layer interconnects 32’ and/or the n-contact interconnects 42 as illustrated in FIG. 1.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip, comprising:
an active LED structure comprising an n-type layer, a p-type layer, and an active layer between the n-type layer and the p-type layer;
a dielectric reflective layer on the active LED structure; and
a lumiphoric material layer between the dielectric reflective layer and the active LED structure, the lumiphoric material layer configured for wavelength conversion of at least a portion of light generated by the active LED structure.

2. The LED chip of claim 1, further comprising a metal reflective layer on the dielectric reflective layer such that the dielectric reflective layer is between the metal reflective layer and the lumiphoric material layer.

3. The LED chip of claim 1, wherein a lateral edge of the of the lumiphoric material layer is bound by the dielectric reflective layer.

4. The LED chip of claim 3, wherein the active LED structure forms a mesa sidewall along portions of the p-type layer, the active layer, and the n-type layer, and the lateral edge of the lumiphoric layer is aligned with the mesa sidewall.

5. The LED chip of claim 4, wherein the dielectric reflective layer extends along the mesa sidewall.

6. The LED chip of claim 1, wherein the lumiphoric material layer comprises a plurality of lumiphoric particles and a binder layer.

7. The LED chip of claim 6, wherein the binder layer comprises aluminum oxide.

8. The LED chip of claim 1, wherein the lumiphoric material layer comprises a plurality of lumiphoric particles arranged in a pattern of regions within a binder layer.

9. A method comprising:
providing an active LED structure comprising an n-type layer, a p-type layer, and an active layer between the n-type layer and the p-type layer;
depositing a plurality of lumiphoric particles on the active LED structure;
deposing a binder layer on the plurality of lumiphoric particles to form a lumiphoric material layer comprising the plurality of lumiphoric particles and the binder layer, the lumiphoric material layer configured for wavelength conversion of at least a portion of light generated by the active LED structure; and
forming a dielectric reflective layer on the lumiphoric material layer such that the lumiphoric material layer is between the dielectric reflective layer and the active LED structure.

10. The method of claim 9, wherein depositing the binder layer comprises atomic layer deposition.

11. The method of claim 10, wherein the binder layer comprises aluminum oxide.

12. The method of claim 9, further comprising selectively removing portions of the plurality of lumiphoric particles over portions of the active LED structure before depositing the binder layer.

13. The method of claim 12, wherein the selectively removing portions of the plurality of lumiphoric particles comprises positioning an imprint stamp on the plurality of lumiphoric particles and lifting the imprint stamp away from the active LED structure to selectively remove the portions of the plurality of lumiphoric particles.

14. The method of claim 13, wherein the imprint stamp comprises a plurality of pedestals that contact the plurality of lumiphoric particles.

15. The method of claim 14, further comprising forming a surface layer on the plurality of pedestals.

16. The method of claim 9, further comprising forming a metal reflective layer on the dielectric reflective layer such that the dielectric reflective layer is between the metal reflective layer and the lumiphoric material layer.

17. A light-emitting diode (LED) wafer, comprising:
an active LED structure comprising an n-type layer, a p-type layer, and an active layer between the n-type layer and the p-type layer; and
a lumiphoric material layer forming a pattern on the active LED structure, the lumiphoric material layer configured for wavelength conversion of at least a portion of light generated by the active LED structure.

18. The LED wafer of claim 17, wherein the lumiphoric material layer comprises a plurality of lumiphoric particles and a binder layer.

19. The LED wafer of claim 18, wherein the binder layer comprises aluminum oxide.

20. The LED wafer of claim 19, wherein the plurality of lumiphoric particles are arranged in a pattern of regions within the binder layer.
